(19) United States
(12) Patent Application Publication
(10) Pub. No.: US 2021/0083413 A1
(43) Pub. Date: Mar. 18, 2021

(54) ELECTRICAL CONNECTOR AND ELECTRICAL CONNECTION SYSTEM

(71) Applicant: Lear Corporation, Southfield, MI (US)

(72) Inventors: Angel MOLINERO BENITEZ, Valls (ES); Marc TENA GIL, Valls (ES); Youssef GHABBOUR, Valls (ES); Josep Maria ROSET RUBIO, Valls (ES)

(73) Assignee: Lear Corporation, Southfield, MI (US)

(21) Appl. No.: 16/568,779

(22) Filed: Sep. 12, 2019

(51) Int. Cl. H01R 12/91; H01R 13/24

(52) U.S. Cl. CPC H01R 12/91; H01R 13/2457

(57) ABSTRACT

An electrical connector is described for electrically connecting an electrical component of a printed circuit board (PCB) to a power bus bar or a housing. The connector includes an electrically conductive element configured for attachment to a surface of the PCB, and a resiliently displaceable electrically conductive feature extending from the electrically conductive element and configured to contact a surface of the bus bar or housing. In response to contact with the surface of the bus bar or housing, the resiliently displaceable electrically conductive feature is urged toward the bus bar or housing to maintain contact therewith and establish an electrical connection between the bus bar or housing and the electrical component of the PCB.

### TECHNICAL FIELD

The following relates to an electrical connector for electrically connecting an electrical component of a printed circuit board (PCB) to a power bus bar or a housing, and an electrical connection system.

### BACKGROUND

Electromagnetic compatibility (EMC) filtering is required in vehicle on-board chargers (OBC) and the like. Such filtering is required not only for internally generated noise, but also for noise produced by other units.

An EMC filter in a printed circuit board (PCB) has to be connected to the power input or output busbar, which connection has certain requirements associated therewith. In that regard, the busbar layout has position tolerances in respect to PCB location. Moreover, the electrical resistance of the connection between the busbar and the PCB has to be minimized. Furthermore, the connection has to be made as near to the exterior connection as possible.

In existing systems, such a connection is made using a wire connection or a rigid busbar connection. However, these types of connections are either long, and thus create a high resistive connection, or too rigid to account for assembly tolerances, or higher cost due to the many separate elements required (e.g., wire, screw, nut, etc.).

A need therefore exists for an improved connector and connection system for an EMC filter in a PCB or similar applications. Such an improved connector and connection system would provide a short electrical path to lower and/or minimize electrical resistance. Such an improved low resistive connector and connection system would also be adaptable to assembly tolerances, having the ability to account for mechanical tolerances in three-dimensions (X, Y, Z). Such an improved connector and connection system would also have a compact design and lower costs in comparison to existing connections.

### SUMMARY

According to one non-limiting exemplary embodiment described herein, an electrical connector is provided for electrically connecting an electrical component of a printed circuit board (PCB) to a power bus bar or a housing. The connector comprises an electrically conductive element configured for attachment to a surface of the PCB, and a resiliently displaceable electrically conductive feature extending from the electrically conductive element and configured to contact a surface of the bus bar or housing. In response to contact with the surface of the bus bar or housing, the resiliently displaceable electrically conductive feature is urged toward the bus bar or housing to maintain contact therewith and establish an electrical connection between the bus bar or housing and the electrical component of the PCB.

According to another non-limiting exemplary embodiment described herein, an electrical connection system is provided that comprises a printed circuit board (PCB) having an electrical component, the PCB having a through-hole formed therein configured to receive a power bus bar comprising a shaft configured to extend through the through-hole, the bus bar configured as part of an electrical power transfer system. The electrical connection system further comprises an electrical connector comprising an electrically conductive element and a resiliently displaceable electrically conductive feature extending from the electrically conductive element. The electrically conductive element is configured for attachment to a surface of the PCB and configured to extend around at least a portion of a perimeter of the through-hole formed in the PCB. The resiliently displaceable electrically conductive feature is configured to contact a surface of the bus bar. In response to contact with the surface of the bus bar, the resiliently displaceable electrically conductive feature is urged toward the bus bar to maintain contact therewith and establish an electrical connection between the bus bar and the electrical component.

According to yet another non-limiting exemplary embodiment described herein, an electrical connection system is provided that comprises a printed circuit board (PCB) having an electrical component, the PCB having a through-hole formed therein configured to receive a power bus bar comprising a shaft configured to extend through the through-hole. The electrical connection system further comprises an electrical connector comprising an electrically conductive element and a resiliently displaceable electrically conductive feature extending from the electrically conductive element. The electrically conductive element is configured for attachment to a surface of the PCB and configured to extend around at least a portion of a perimeter of the through-hole formed in the PCB. The bus bar is configured to be arranged in a housing having an electrically conductive surface oriented parallel to the surface of the PCB and configured to provide an electrical ground to the electrical component. The resiliently displaceable electrically conductive feature is configured to contact the electrically conductive surface of the housing. In response to contact with the electrically conductive surface of the housing, the resiliently displaceable electrically conductive feature is urged toward the housing to maintain contact therewith and provide the electrical ground to the electrical component.

A detailed description of these and other non-limiting exemplary embodiments of an electrical connector and an electrical connection system is set forth below together with the accompanying drawings.

### BRIEF DESCRIPTION OF THE DRAWINGS

FIG. 1 is a perspective view of an exemplary application for the non-limiting exemplary embodiments of the present disclosure;

FIG. 2A is a bottom perspective view of an electrical connector and electrical connection system according to one non-limiting exemplary embodiment of the present disclosure;

FIG. 2B is a top perspective view of the electrical connection system of FIG. 1A according to one non-limiting exemplary embodiment of the present disclosure;

FIG. 3A is a perspective view of an electrical connector according to one non-limiting exemplary embodiment of the present disclosure;

FIG. 3B is a perspective view of another electrical connector according to another non-limiting exemplary embodiment of the present disclosure;

FIG. 3C is a perspective view of another electrical connector according to another non-limiting exemplary embodiment of the present disclosure;

FIG. 3D is a perspective view of another electrical connector according to another non-limiting exemplary embodiment of the present disclosure;

FIG. 3E is a perspective view of another electrical connector according to another non-limiting exemplary embodiment of the present disclosure;

FIG. 4A is a cross-sectional view of another electrical connector according to another non-limiting exemplary embodiments of the present disclosure;

FIG. 4B is a cross-sectional view of another electrical connector according to another non-limiting exemplary embodiments of the present disclosure;

FIG. 4C is a cross-sectional view of another electrical connector according to another non-limiting exemplary embodiments of the present disclosure;

FIG. 4D is a cross-sectional view of another electrical connector according to another non-limiting exemplary embodiments of the present disclosure;

FIG. 5 is a cross-sectional view of an electrical connector and electrical connection system of FIG. 1A according to one non-limiting exemplary embodiment of the present disclosure;

FIG. 6 is a cross-sectional view of electrical connectors and electrical connection systems according to one non-limiting exemplary embodiment of the present disclosure;

FIG. 7 is a cross-sectional view of electrical connectors and electrical connection systems according to another non-limiting exemplary embodiment of the present disclosure; and

FIG. 8 is a cross-sectional view of electrical connectors and electrical connection systems according to another non-limiting exemplary embodiment of the present disclosure.

### DETAILED DESCRIPTION

As required, detailed non-limiting embodiments are disclosed herein. However, it is to be understood that the disclosed embodiments are merely exemplary and may take various and alternative forms. The figures are not necessarily to scale, and features may be exaggerated or minimized to show details of particular components, elements, features, items, members, parts, portions, or the like. Therefore, specific structural and functional details disclosed herein are not to be interpreted as limiting, but merely as a representative basis for teaching one skilled in the art.

With reference to the Figures, a more detailed description of non-limiting exemplary embodiments of an electrical connector for electrically connecting an electrical component of a printed circuit board (PCB) to a power bus bar or a housing and an electrical connection system will be provided. For ease of illustration and to facilitate understanding, like reference numerals have been used herein for like components and features throughout the drawings.

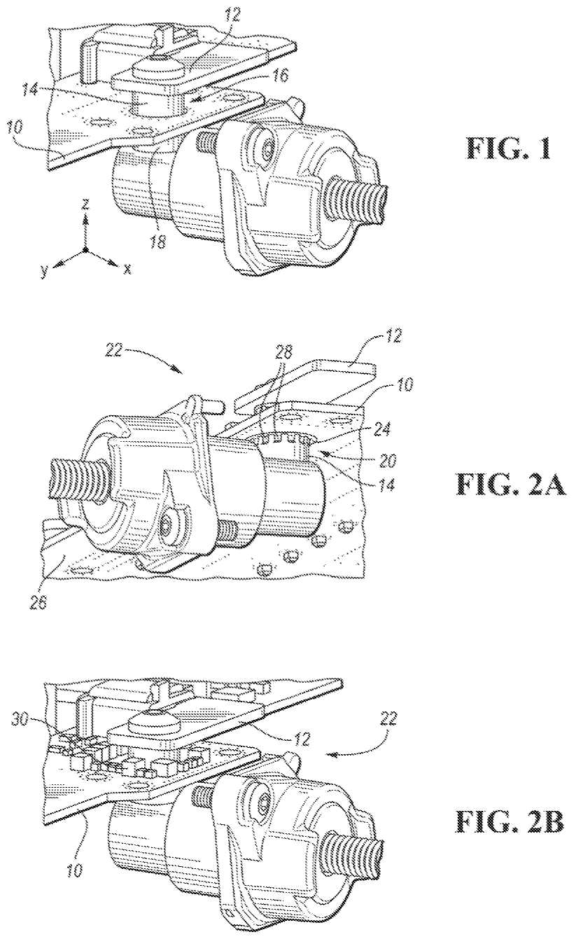

As previously described, EMC filtering is required in a vehicle OBC and the like, not only for internally generated noise but also for noise produced by other units. FIG. 1 illustrates a perspective view of a PCB 10 and a power busbar 12, which may comprise a shall 14 that extends through a through-hole 16 formed in the PCB 10. An EMC filter (not shown) in the PCB 10 has to be connected to the power input or output busbar 12. Such a connection has certain requirements, including that layout of the busbar 12 has certain X, Y, and Z position tolerances in respect to its location relative to the PCB 10. Moreover, the electrical resistance of the connection between the busbar 12 and the PCB 10 has to be minimized. Furthermore, the connection between the busbar 12 and the PCB10 has to be made as near to the exterior connection 18 as possible, in existing systems, such an EMC filter connection is made using a wire connection or a rigid busbar connection. However, these types of connections are either long, and thus create a high resistive connection, or too rigid to account for assembly tolerances, or higher cost due to the many separate elements required (e.g., wire, screw, nut, etc.).

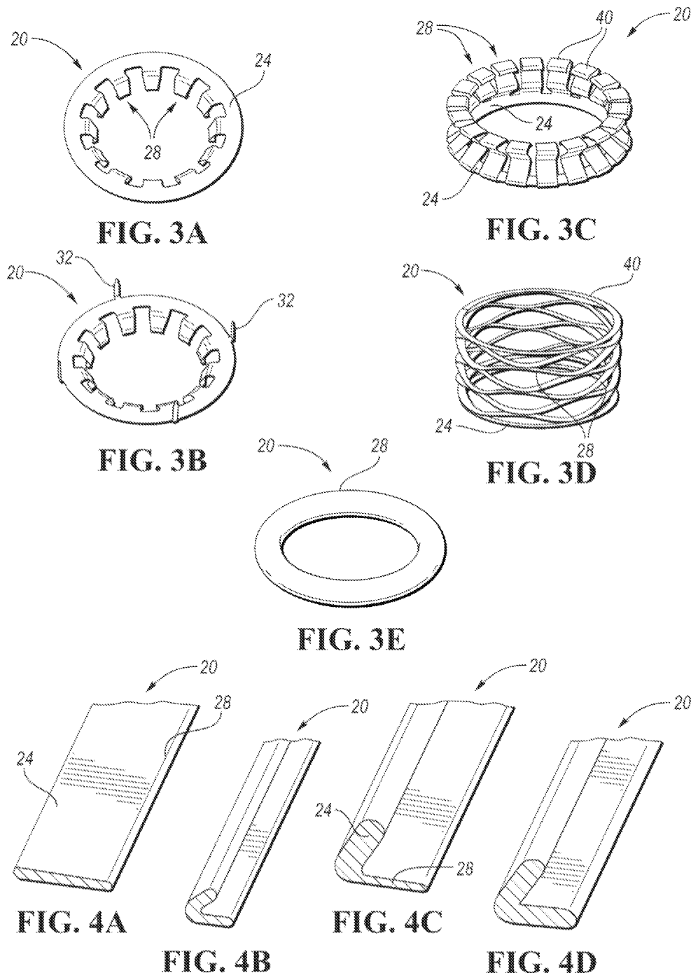

FIG. 2A illustrates a bottom perspective view of a PCB 10 and power busbar 12 with an electrical connector 20 and an electrical connection system 22 according to one non-limiting exemplary embodiment of the present disclosure. As seen therein, and with continuing reference to FIG. 1, the electrical connector 20 may comprise an electrically conductive element 24 that may be attached to a surface 26 of the PCB 10 around the through-hole 16 formed in the PCB 10. Such attachment of the electrically conductive element 24 to the surface 26 of the PCB 10 may be accomplished by soldering, such as with a surface mount device, conductive adhesive, press-fit features 32 (see FIGS. 3B, 8) of the connector 20, or any other known means or method. One or more electrically conductive features 28 may extend from the electrically conductive element 24. Such electrically conductive features 28 may be resiliently displaceable to contact a surface of the busbar 12, such as a surface of the busbar shaft 14 that extends through the through-hole 16 in the PCB 10. In response to contact with the surface of the busbar 12, the resiliently displaceable electrically conductive features 28 may be urged toward the busbar 12 to maintain contact therewith and establish an electrical connection with the busbar 12.

FIG. 2B illustrates a top perspective view of the PCB 10 and power busbar 14 of FIG. 2A. As seen therein, and with continuing reference to FIG. 2A, the electrical connector 20 and an electrical connection system 22 according to one non-limiting exemplary embodiment of the present disclosure establishes an electrical connection between the power busbar 12 and EMC filter components 30 mounted on a surface of the PCB 10. In such a fashion, the electrical connector 20 and/or connection system 22 overcome the problems associated with existing connections of an EMC filter in a PCB or similar applications. The connector 20 and connection system 22 provide a short electrical path between the busbar 12 and the EMC filter components 30 or other components to lower and/or minimize electrical resistance. The connector 20 and connection system 22 are also adaptable to assembly tolerances, having the ability to account for mechanical tolerances in three-dimensions (X, Y, Z). The connector 20 and connection system 22 also have a compact design and lower costs in comparison to existing connections.

FIGS. 3A and 3B illustrate perspective views of electrical connectors 20 according to various non-limiting exemplary embodiment of the present disclosure. As seen in FIG. 3A, and with continuing reference to FIGS. 1 and 2A, the connector 20 may comprise the electrically conductive element 24 configured for attachment to the surface 26 of the PCB 10 and one or more electrically conductive features 28 extending from the electrically conductive element 24. The electrically conductive features 28 may comprise a plurality of projections and, as previously noted, may be resiliently displaceable to contact a surface of the busbar 12, such as a surface of the busbar shaft 14 that extends through the through-hole 16 in the PCB 10. In response to contact with the surface of the busbar 12, the resiliently displaceable electrically conductive features 28 may be urged toward the busbar 12 to maintain contact therewith and establish an electrical connection with the busbar 12. In that regard, it should be noted that the resiliently displaceable electrically conductive features 28, while illustrated in FIGS. 3A and 3B as comprising multiple substantially flat and/or planar sections with intervening joints or bends and having a substantially L-shaped configuration, may have or take any form, shape, orientation, or configuration suitable for making contact with a surface of the busbar 12.

The electrically conductive element 24 may be attached to the surface 26 of the PCB 10 around the through-hole 16 formed in the PCB 10. As previously noted, such attachment may be accomplished by soldering, conductive adhesive, press-fit features 32 (see FIGS. 3B, 8 of the connector 20, or any other known means or method. In that regard, as seen in FIG. 3B, one or more press-fit features 32 may extend from the electrically conductive element 24 in a direction generally opposite that direction in which the resiliently displaceable electrically conductive features 28 extend from the electrically conductive element 24. The press-fit features 32 are configured for insertion in receptacles or holes 56 (see FIG. 8) formed in the PCB 10, which holes may be electrically conductive vias, to thereby mechanically and/or electrically attach the electrically conductive element 24 of the connector 20 to the surface 26 of the PCB 10 and/or an electrical component in or on the PCB 10, such as EMC filter components 30. It should be noted that, as used herein, the term electrical component includes any electrically conductive member, item, element, feature, device, or the like, including any discrete electrical component such as a resistor, capacitor, or the like that may be mounted on a surface of the PCB 10 as part of an electrical circuit or device, any electrical component that may be integrally formed with or as pan of the PCB, as well as any electrically conductive line, lead, trace, track, node, island, via or the like that may be formed on a surface of the PCB 10 or internally within the PCB 10.

It should also be noted that the through hole 16 in the PCB 10, while illustrated herein as circular, may have any alternative shape. Similarly, while illustrated herein as cylindrical, the shaft 14 of the busbar 12 that extends through the through-hole 16 in the PCB 10 may also have any alternative shape or configuration. Still further, while illustrated herein as circular, substantially flat and/or planar, and extending fully around the perimeter of the through-hole 16 in the PCB 10, the electrically conductive element 24 may also have any alternative shape or configuration and may extend around any portion of the perimeter of the through-hole 16 in the PCB.

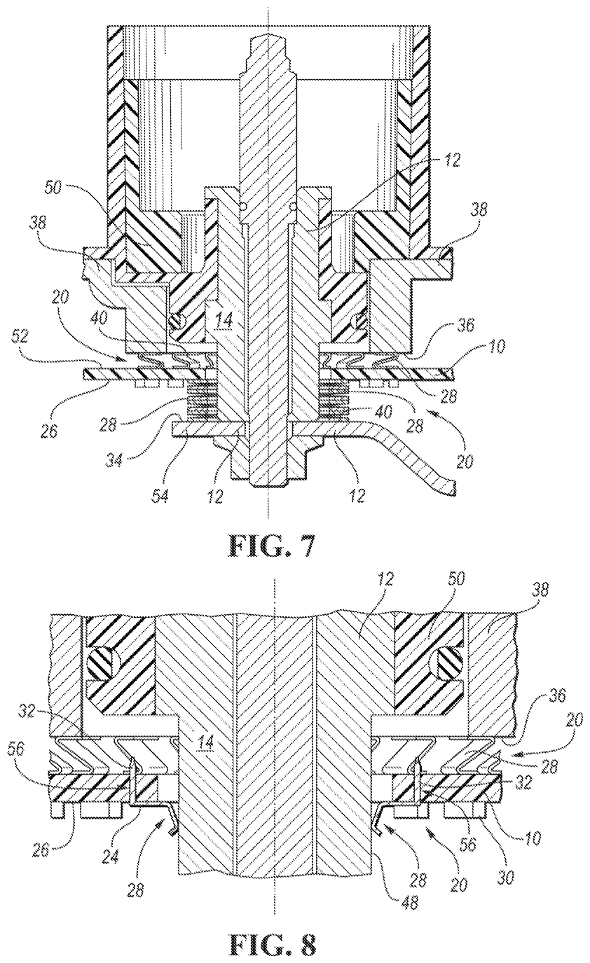

FIGS. 3C-3E illustrate perspective views of electrical connectors 20 according to various non-limiting exemplary embodiments of the present disclosure, while FIGS. 4A-40 illustrate cross-sectional views of electrical connectors 20 according to various non-limiting exemplary embodiments of the present disclosure. As seen therein, the connector 20 may comprise an electrically conductive element 24 and one or more electrically conductive features 28 extending from the electrically conductive element 24. Such electrically conductive features 28 may be resiliently displaceable to contact a surface of the busbar shall 14 or other surface 34 of the busbar 12 (see FIG. 7), or to contact an electrically conductive surface 36 of a housing 38 (see FIGS. 6-8). In response to contact with the surface of the busbar 12 or the surface 36 of the housing 38, the resiliently displaceable electrically conductive features 28 may be urged toward the busbar 12 or housing 38 to maintain contact therewith and establish an electrical power connection with the busbar 12 or an electrical ground connection with the housing 38.

As seen in FIGS. 3C and 3D, the electrically conductive features 28 may have a surface 40 configured and or adapted to contact the surface 34 of the busbar 12 (see FIG. 7) or the electrically conductive surface 36 of the housing 38 (see FIGS. 6-8). It should be noted that the resiliently displaceable electrically conductive features 28, while illustrated in FIG. 3C as comprising multiple substantially flat and/or planar sections with intervening joints or bends and having a substantially Σ-shaped configuration, may have or take any form, shape, orientation, or configuration (e.g., substantially Z-shaped) suitable for making contact with the surface 34 of the busbar 12 (see FIG. 7) or the electrically conductive surface 36 of the housing 38 (see FIGS. 6-8).

As seen in FIG. 3D, the connector 20 may alternatively have a substantially cylindrical shape and be formed from any known type of spring. As seen therein, the resiliently displaceable features 28 of the connector may comprise web-like elements forming the spring. Alternatively, the connector 20 may have a substantially cylindrical shape and comprise a coiled spring (not shown) having a single resiliently displaceable feature 28 forming the coil. As seen in FIG. 3E, the connector 20 may alternatively be formed of any known type of conductive elastomer which may comprise a single electrical displaceable feature 28. As seen in FIGS. 4A-4D, the connector 20 may be formed from any known type of metalized gasket, which may comprise a braided foam or other material. As also seen therein, the connector 20 may comprise an electrically conductive element 24 for attachment to a surface 26 of a PCB 10 and a single resiliently displaceable feature 28, such as a flange, extending from the electrically conductive element 24 at any angle.

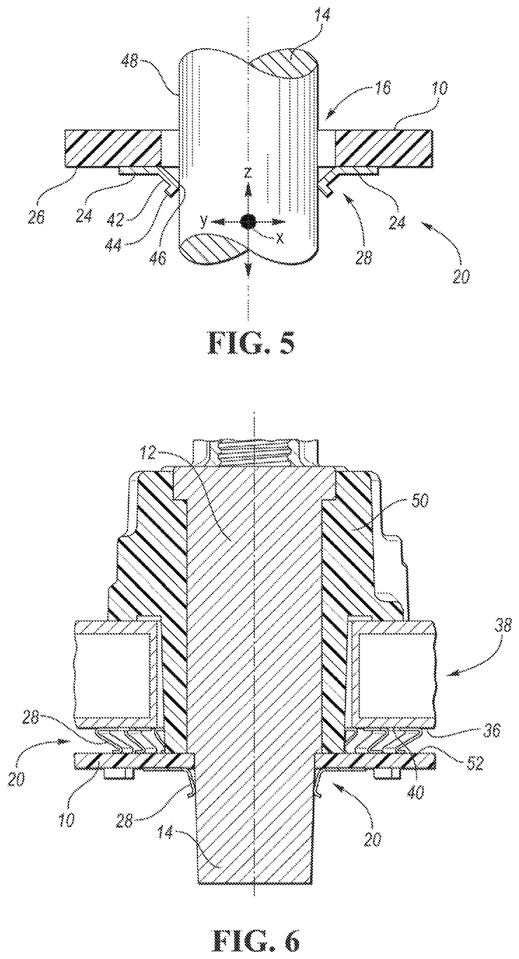

FIGS. 5-8 illustrate cross-sectional views of electrical connectors and electrical connection systems according to various non-limiting exemplary embodiments of the present disclosure. In that regard, FIG. 5 illustrates a cross-sectional view of the electrical connector 20 and electrical connection system 22 shown in FIG. 2A. As seen in FIG. 5, and with continuing reference to FIG. 2A, the connector 20 may comprise the electrically conductive element 24 configured or adapted for attachment to the surface 26 of the PCB 10 and the electrically conductive features 28 extending from the electrically conductive element 24. Each electrically conductive feature 28 may comprise a first portion 42 extending from the electrically conductive element 24 and a second portion 44 extending from the first portion 42 and attached to the first portion at a bend or a joint 46.

As previously described, the electrically conductive features 28 may be resiliently displaceable to contact a surface 48 of the busbar shaft 14 that extends through the through-hole 16 in the PCB 10, which surface 48 is non-parallel with the surface 26 of the PCB 10. In response to contact with the surface 48 of the busbar 12, the resiliently displaceable electrically conductive features 28 may be urged toward the busbar 12 to maintain contact therewith and establish an electrical connection with the busbar 12. It should again be noted that the resiliently displaceable electrically conductive features 28, while illustrated in FIG. 5 as comprising multiple substantially flat and/or planar sections or portions 42, 44 with intervening bends or joints 46 and having a substantially L-shaped configuration, may have or take any form, shape, orientation, or configuration suitable for making contact with the surface 48 of the busbar shaft 42. In that regard, each resiliently displaceable electrically conductive feature 28 is shown in FIG. 5 as contacting the surface 48 of the busbar shaft 14 only at joint 46. Alternatively, the electrically conductive features 28 may be configured or adapted to contact the surface 48 of the busbar shaft 14 at any point, points, portion, or portions of the resiliently displaceable feature 28.

In such a fashion, the electrically conductive element 24 and resiliently displaceable electrically conductive features 28 of the connector 20 overcome the problems associated with existing connections of an EMC filter in a PCB or similar applications by providing a short electrical path between the busbar shaft 14 and electrical components to lower and/or minimize electrical resistance. The electrically conductive element 24 and resiliently displaceable electrically conductive features 28 of the connector 20 are also adaptable to assembly tolerances, having the ability to account for mechanical tolerances in the X, Y, and Z dimensions shown (where the X dimension extends in a direction normal to the plane of the drawing sheet). The connector 20 comprising the electrically conductive element 24 and resiliently displaceable electrically conductive features 28 of the connector 20 also have a compact design and lower costs in comparison to existing connections.

As seen in FIGS. 6 and 7, the busbar 12 may be configured to be arranged in a housing, which may comprise a conductive portion 38 (e.g., aluminum or other conductive material) and a non-conductive portion 50 (e.g., plastic or other non-conductive material). The non-conductive housing 50 electrically isolates the busbar 12 from the conductive housing 38, which may be configured as an electrical ground (e.g., by an external connection to the vehicle chassis). One electrical connector 20 according to the present disclosure may comprise resiliently displaceable electrically conductive features 28 configured to contact an electrically conductive surface 36 of the housing 38. The resiliently displaceable electrically conductive features 28 may have a surface 40 configured and/or adapted to contact the conductive surface 36 of the housing 38. In that regard, the electrically conductive surface 36 of the housing 38 with which the surface 40 of the resiliently displaceable electrically conductive features 28 makes contact is substantially parallel to a surface 52 of the PCB to which the electrical connector 20 is attached. In response to contact with the conductive surface 36 of the housing 38, the resiliently displaceable electrically conductive features 28 may be urged toward the housing 38 to maintain contact therewith and establish an electrical ground connection with the housing 38.

Still referring to FIG. 7, the busbar 12 may be provided with an electrically conductive flange or rim 54 extending from the busbar shaft 14. In that regard, while shown in FIG. 7 as an attachment to the busbar shaft 14 as part of a busbar assembly, the rim 54 may alternatively be integrated with the busbar shaft 14. Another electrical connector 20 according to the present disclosure may comprise resiliently displaceable electrically conductive features 28 configured to contact a surface 34 of the rim 54 of the busbar 12. The resiliently displaceable electrically conductive features 28 may have a surface 40 configured and/or adapted to contact the conductive surface 34 of the busbar 12. The surface 34 of the busbar 12 with which the surface 40 of the resiliently displaceable electrically conductive features 28 makes contact is substantially parallel to a surface 26 of the PCB 10 to which the electrical connector 20 is attached. In response to contact with the surface 34 of the busbar 12, the resiliently displaceable electrically conductive features 28 may be urged toward the busbar 12 to maintain contact therewith and establish an electrical connection with the busbar 12.

FIG. 8 illustrates a cross-sectional view of an electrical connector 20 according to one non-limiting exemplary embodiment of the present disclosure that comprises an electrically conductive element 24 adapted or configured for attachment to a surface 26 of a PCB 10 and resiliently displaceable electrically conductive features 28 extending from the electrically conductive element 24. As previously described, the electrically conductive features 28 may be resiliently displaceable to contact a surface 48 of the busbar shaft 14 that extends through the through-hole 16 in the PCB 10, which surface 48 is non-parallel with the surface 26 of the PCB 10. In response to contact with the surface 48 of the busbar 12, the resiliently displaceable electrically conductive features 28 may be urged toward the busbar 12 to maintain contact therewith and establish an electrical connection with the busbar 12.

As seen in FIG. 8, and with reference again to FIG. 3B, one or more press-fit features 32 may extend from the electrically conductive element 24 in a direction generally opposite that direction in which the resiliently displaceable electrically conductive features 28 extend from the electrically conductive element 24. The press-fit features 32, which may be of any known type, are configured for insertion in receptacles or holes 56 formed in the PCB 10, which holes 56 may be electrically conductive vias, to thereby mechanically and/or electrically attach the electrically conductive element 24 of the connector 20 to the surface 26 of the PCB 10 and/or an electrical component in or on the PCB 10, such as EMC filter components 30. It should again be noted that, as used herein, the term electrical component includes any electrically conductive member, item, element, feature, device, or the like, including any discrete electrical component such as a resistor, capacitor, or the like that may be mounted on a surface of the PCB 10 as part of an electrical circuit or device, any electrical component that may be integrally formed with or as part of the PCB, as well as any electrically conductive line, lead, trace, track, node, island, via or the like that may be formed on a surface of the PCB 10 or internally within the PCB 10.

As also seen in FIG. 8, and as previously described in greater detail connection with FIGS. 6 and 7, another electrical connector 20 may comprise resiliently displaceable electrically conductive features 28 configured to contact an electrically conductive surface 36 of the housing 38. In response to contact with the conductive surface 36 of the housing 38, the resiliently displaceable electrically conductive features 28 may be urged toward the housing 38 to maintain contact therewith and establish an electrical ground connection with the housing 38.

Thus, with reference now to FIGS. 1-8, in one non-limiting exemplary embodiment the present disclosure describes an electrical connector 20 for electrically connecting an electrical component of a PCB 10 to a power bus bar 12 or a housing 38. The connector 20 may comprise an electrically conductive element 24 configured for attachment to a surface 26 of the PCB 10 and a resiliently displaceable electrically conductive feature 28 extending from the electrically conductive element 24 and configured to contact a surface of the bus bar 12 or housing 38. In response to contact with the surface of the bus bar 12 or housing 38, the resiliently displaceable electrically conductive feature 28 is urged toward the bus bar 12 or housing 38 to maintain contact therewith and establish an electrical connection between the bus bar 12 or housing 38 and the electrical component of the PCB 10. Once again, as used herein, the term electrical component includes any electrically conductive member, item, element, feature, device, or the like, including any discrete electrical component such as a resistor, capacitor, or the like that may be mounted on a surface of the PCB 10 as part of an electrical circuit or device, any electrical component that may be integrally formed with or as part of the PCB, as well as any electrically conductive line, lead, trace, track, node, island, via or the like that may be formed on a surface of the PCB 10 or internally within the PCB 10.

The electrically conductive element 24 may comprise a strip configured to extend around at least a portion of a perimeter of a through-hole 16 formed in the PCB 10 and configured to receive the bus bar 12. The strip of the electrically conductive element 24 may alternatively be configured to extend around the entire perimeter of the through-hole 16 formed in the PCB 10. The bus bar 12 may comprise a shaft 14 configured to extend through the through-hole 16, the shaft 14 having a surface 48 oriented non-parallel to the surface 26 of the PCB 10, and the resiliently displaceable electrically conductive feature 28 may be configured to contact the surface 48 of the shaft 14 of the bus bar 12 to ensure electrical contact to the electrical component of the PCB 10. The bus bar 12 may have a surface 34 oriented parallel to the surface 26 of the PCB 10, and the resiliently displaceable electrically conductive feature 28 may be configured to contact the surface 34 of the bus bar 12 oriented parallel to the surface 26 of the PCB 10 to ensure electrical contact to the electrical component of the PCB 10. The bus bar 12 may be configured to be arranged in a housing 38 having an electrically conductive surface 36 oriented parallel to the surface 52 of the PCB, and the resiliently displaceable electrically conductive feature 28 may be configured to contact the electrically conductive surface 36 of the housing to provide an electrical ground to the electrical component of the PCB 10.

The resiliently displaceable electrically conductive feature 28 of the connector 20 may comprises a spring, a metalized gasket, a flange, or a conductive elastomer. The resiliently displaceable electrically conductive feature 28 may alternatively comprise a plurality of projections. A surface of the electrically conductive element 24 may be configured for electrical connection to an electrical component comprising an electrically conductive trace formed on a surface 26, 52 of the PCB 10 or an electrically conductive via formed in the PCB 10. The electrical connection of the electrically conductive element 24 of the connector to a surface 26, 52 of the PCB 10 may be formed by solder, conductive adhesive, or a press-fit feature 32 of the electrically conductive element 24.

In another non-limiting exemplary embodiment, the present disclosure describes an electrical connection system 22 comprising a PCB 10 having an electrical component, the PCB 10 having a through-hole 16 formed therein configured to receive a power bus bar 12 comprising a shaft 14 configured to extend through the through-hole 16, the bus bar 12 configured as part of an electrical power transfer system. The electrical connection system 22 may further comprise an electrical connector 20 comprising an electrically conductive element 24 and a resiliently displaceable electrically conductive feature 28 extending from the electrically conductive element 24. The resiliently displaceable electrically conductive feature 28 may comprise a spring, a metalized gasket, a flange, a conductive elastomer, or a plurality of projections.

The electrically conductive element 24 may be configured for attachment to a surface 26 of the PCB 10 and configured to extend around at least a portion of a perimeter of the through-hole 16 formed in the PCB 10. The resiliently displaceable electrically conductive feature 28 may be configured to contact a surface 34, 48 of the bus bar 12. The surface 34 of the bus bar 12 may be oriented parallel to the surface 26 of the PCB 10. Alternatively, the surface 48 of the bus bar 12 may be a surface of the shaft 14 oriented non-parallel to the surface 26 of the PCB 10. In response to contact with the surface 34, 48 of the bus bar, the resiliently displaceable electrically conductive feature 28 may be urged toward the bus bar 12 to maintain contact therewith and establish an electrical connection between the bus bar 12 and the electrical component. To achieve a stronger connection between the electrically conductive feature 28 and the surface 34, 48 of the bus bar 12, the electrical connection system 22 may further comprise an attachment feature (not shown) for attaching the resiliently displaceable electrically conductive feature 28 to the surface 34, 48 of the bus bar 12. Such an attachment feature may comprise a conductive adhesive, or a resin to cover and/or protect the contact from any external agent or chemical degradation. Alternatively, such an attachment feature may comprise an additional element, such as an elastic ring, to reinforce the urging of the resiliently displaceable electrically conductive feature 28 toward the surface 34, 48 of the bus bar 12 and improve the electrical contact therebetween.

In yet another non-limiting exemplary embodiment, the present disclosure describes an electrical connection system comprising a PCB 10 having an electrical component, the PCB 10 having a through-hole 16 formed therein configured to receive a power bus bar 12 comprising a shaft 14 configured to extend through the through-hole 16. The electrical connection system 22 may further comprise an electrical connector 20 comprising an electrically conductive element 24 and a resiliently displaceable electrically conductive feature 28 extending from the electrically conductive element 24. The resiliently displaceable electrically conductive feature 28 may comprise a spring, a metalized gasket, a flange, a conductive elastomer, or a plurality of projections.

The electrically conductive element 24 may be configured for attachment to a surface 52 of the PCB 10 and configured to extend around at least a portion of a perimeter of the through-hole 16 formed in the PCB 10. The bus bar 12 may be configured to be arranged in a housing 38 having an electrically conductive surface 36 oriented parallel to the surface 52 of the PCB 10 and configured to provide an electrical ground to the electrical component. The resiliently displaceable electrically conductive feature 28 may be configured to contact the electrically conductive surface 36 of the housing 38. In response to contact with the electrically conductive surface 36 of the housing 38, the resiliently displaceable electrically conductive feature 28 may be urged toward the housing 38 to maintain contact therewith and provide the electrical ground to the electrical component. Once again, to achieve a stronger connection between the electrically conductive feature 28 and the surface 34, 48 of the bus bar 12, the electrical connection system 22 may further comprise an attachment feature (not shown) for attaching the resiliently displaceable electrically conductive feature 28 to the surface 34, 48 of the bus bar 12, which attachment feature may comprise a conductive adhesive, resin, or elastic ring as previously described.

The electrical connector 20 and/or connection system 22 of the present disclosure thus overcome the problems associated with existing connections of an EMC filter in a PCB or similar applications. The connector 20 and connection system 22 provide a short electrical path between the busbar 12 and the EMC filter components 30 or other components to lower and/or minimize electrical resistance. The connector 20 and connection system 22 are also adaptable to assembly tolerances, having the ability to account for mechanical tolerances in three-dimensions (X, Y, Z). The connector 20 and connection system 22 also have a compact design and lower costs in comparison to existing connections.

As is readily apparent from the foregoing, various non-limiting embodiments of an electrical connector for electrically connecting an electrical component of a printed circuit board (PCB) to a power bus bar or a housing and an electrical connection system have been described. While various embodiments have been illustrated and described herein, they are exemplary only and it is not intended that these embodiments illustrate and describe all those possible. Instead, the words used herein are words of description rather than limitation, and it is understood that various changes may be made to these embodiments without departing from the spirit and scope of the following claims.

1. An electrical connector for electrically connecting an electrical component of a printed circuit board (PCB) to a power bus bar or a housing, the PCB having a through-hole formed therein, the connector comprising:
an electrically conductive element configured for attachment to a surface of the PCB; and
a resiliently displaceable electrically conductive feature extending from the electrically conductive element and configured to contact a surface of the bus bar or housing, wherein, in response to contact with the surface of the bus bar or housing, the resiliently displaceable electrically conductive feature is urged toward the bus bar or housing to maintain contact therewith and establish an electrical connection between the bus bar or housing and the electrical component of the PCB;
wherein the electrically conductive element and the resiliently displaceable electrically conductive feature are configured for arrangement outside the through-hole and on a same side of the surface of the PCB.

2. The electrical connector of claim 1 wherein the electrically conductive element comprises a strip configured to extend around at least a portion of a perimeter of the through-hole formed in the PCB and wherein, to ensure electrical contact to the electrical component of the PCB, the resiliently displaceable electrically conductive feature is configured to contact a surface of a shaft of the power bus bar extending through the through-hole, the surface of the shaft oriented non-parallel to the surface of the PCB.

3. The electrical connector of claim 2 wherein the strip is configured to extend around the perimeter of the through-hole formed in the PCB.

4. The electrical connector of claim 1 wherein the electrically conductive element comprises a strip configured to extend around at least a portion of a perimeter of the through-hole formed in the PCB and wherein, to ensure electrical contact to the electrical component of the PCB, the resiliently displaceable electrically conductive feature is configured to contact a surface of a shaft of the power bus bar extending through the through-hole, the surface of the shaft oriented parallel to the surface of the PCB.

5. The electrical connector of claim 4 wherein the strip is configured to extend around the perimeter of the through-hole formed in the PCB.

6. The electrical connector of claim 1 wherein the electrically conductive element comprises a strip configured to extend around at least a portion of a perimeter of the through-hole formed in the PCB and wherein, to provide an electrical ground to the electrical component of the PCB, the resiliently displaceable electrically conductive feature is configured to contact an electrically conductive surface of the housing oriented parallel to the surface of the PCB, the housing having the bus bar arranged therein, the bus bar having a shaft extending through the through-hole of the PCB.

7. The electrical connector of claim 6 wherein the strip is configured to extend around the perimeter of the through-hole formed in the PCB.

8. The electrical connector of claim 1 wherein the resiliently displaceable electrically conductive feature comprises a spring, a metalized gasket, a flange, or a conductive elastomer.

9. The electrical connector of claim 1 wherein the resiliently displaceable electrically conductive feature comprises a plurality of projections.

10. The electrical connector of claim 1 wherein the electrically conductive element is configured for electrical connection to the electrical component, and wherein the electrical connection is formed by solder, conductive adhesive, or a press-fit feature of the electrically conductive element to attach the electrically conductive element to an electrically conductive trace formed on the surface of the PCB or an electrically conductive via formed in the PCB.

11. An electrical connection system comprising:
a printed circuit board (PCB) having an electrical component, the PCB having a through-hole formed therein configured to receive a power transfer system bus bar having a shaft to extend through the through-hole; and
an electrical connector comprising an electrically conductive element and a resiliently displaceable electrically conductive feature extending from the electrically conductive element;
wherein the electrically conductive element is configured for attachment to a surface of the PCB and configured to extend around at least a portion of a perimeter of the through-hole formed in the PCB;
wherein the resiliently displaceable electrically conductive feature is configured to contact a surface of the bus bar, and wherein, in response to contact with the surface of the bus bar, the resiliently displaceable electrically conductive feature is urged toward the bus bar to maintain contact therewith and establish an electrical connection between the bus bar and the electrical component; and
wherein the electrically conductive element and the resiliently displaceable electrically conductive feature are configured for arrangement outside the through-hole and on a same side of the surface of the PCB.

12. The electrical connection system of claim 11 wherein the resiliently displaceable electrically conductive feature is configured to contact a surface of the bus bar oriented parallel to the surface of the PCB.

13. The electrical connection system of claim 11 wherein the resiliently displaceable electrically conductive feature is configured to contact a surface of the bus bar shaft oriented non-parallel to the surface of the PCB.

14. The electrical connection system of claim 11 wherein the resiliently displaceable electrically conductive feature comprises a spring, a metalized gasket, a flange, or a conductive elastomer.

15. The electrical connection system of claim 13 wherein the resiliently displaceable electrically conductive feature comprises a plurality of projections.

16. The electrical connection system of claim 13 further comprising an attachment feature for attaching the resiliently displaceable electrically conductive feature to the surface of the bus bar.

17. An electrical connection system comprising:
a printed circuit board (PCB) having an electrical component, the PCB having a through-hole formed therein configured to receive a power bus bar having a shaft to extend through the through-hole; and
an electrical connector comprising an electrically conductive element and a resiliently displaceable electrically conductive feature extending from the electrically conductive element;
wherein the electrically conductive element is configured for attachment to a surface of the PCB and configured to extend around at least a portion of a perimeter of the through-hole formed in the PCB;
wherein the resiliently displaceable electrically conductive feature is configured to contact an electrically conductive surface of a housing having the bus bar arranged therein, the electrically conductive surface oriented parallel to the surface of the PCB, and wherein, in response to contact with the electrically conductive surface of the housing, the resiliently displaceable electrically conductive feature is urged toward the housing to maintain contact therewith and provide an electrical ground to the electrical component; and
wherein the electrically conductive element and the resiliently displaceable electrically conductive feature are configured for arrangement outside the through-hole and on a same side of the surface of the PCB.

18. The electrical connection system of claim 17 wherein the resiliently displaceable electrically conductive feature comprises a spring, a metalized gasket, a flange, or a conductive elastomer.

19. The electrical connection system of claim 17 wherein the resiliently displaceable electrically conductive feature comprises a plurality of projections.

20. The electrical connection system of claim 17 further comprising an attachment feature for attaching the resiliently displaceable electrically conductive feature to the electrically conductive surface of the housing.
